(19) United States
(12) Patent Application Publication
(10) Pub. No.: US 2007/0210367 A1
(43) Pub. Date: Sep. 13, 2007

(54) Storage capacitor and method for producing such a storage capacitor

(75) Inventors: Henry Bernhardt, Dresden (DE); Thomas Hecht, Dresden (DE); Michael Stadtmueller, Dresden (DE); Christian Kapteyn, Berlin (DE); Uwe Schroder, Dresden (DE); Yeong-Kwan Kim, Dresden (DE); Andreas Spitzer, Ottobrunn (DE)

Correspondence Address: MORRISON & FOERSTER LLP, 1650 TYSONS BOULEVARD, SUITE 400, MCLEAN, VA, 22102, US

(73) Assignee: QIMONDA AG, Munchen (DE)

(21) Appl. No.: 11/606,381

(22) Filed: Nov. 30, 2006

(30) Foreign Application Priority Data
Dec. 1, 2005 (DE) 102005057255.3-33

(51) Int. Cl. H01L 29/94

(52) U.S. Cl. 257/306

(57) ABSTRACT

A storage capacitor includes a first electrode layer, second electrode layer and a dielectric interlayer arranged between the first electrode layer and the second electrode layer. The dielectric interlayer contains a high-k dielectric and at least one silicon-containing component.

### BACKGROUND OF THE INVENTION

1. Field of the Invention

The invention relates to a storage capacitor and a method for producing such a storage capacitor, a memory, preferably a dynamic random access memory (DRAM), and a computer system.

2. Description of the Related Art

Semiconductor memories, primarily DRAMs, are generally realized as a memory cell matrix on a semiconductor wafer. In this case, the memory cells comprise a storage capacitor and a selection transistor. During a reading or writing operation, the storage capacitor is charged or discharged, respectively, with an electrical charge corresponding to a data unit, via the selection transistor. For this purpose, the selection transistor is addressed via a bit or word line with the aid of a peripheral logic having switching transistors.

An essential main focus in the technological development of semiconductor memories is the storage capacitor. In order to provide for a sufficient storage capacitance in conjunction with a small cross-sectional area, the storage capacitors are therefore realized three-dimensionally. In this case, trench capacitors and stacked capacitors have gained acceptance as essential embodiments of three-dimensional storage capacitors. In the case of trench capacitors, a trench is etched into the semiconductor substrate, said trench being filled with a dielectric interlayer and a first storage electrode layer, a doped region of the semiconductor substrate around the trench serving as a second storage electrode layer. The selection transistor of the memory cell is usually formed as a planar field effect transistor on the semiconductor surface alongside the trench capacitor, one transistor electrode being connected to one electrode layer of the trench capacitor.

Stacked capacitors, by contrast, are formed on the surface of the semiconductor substrate, a first storage electrode layer being embodied in the form of a crown that is isolated from a second storage electrode layer by means of a dielectric interlayer. In this case, the selection transistor of the memory cell is provided below the stacked capacitor in the form of a planar field effect transistor, one transistor electrode being connected to the crown-type storage electrode layer of the stacked capacitor.

On account of the still increasing miniaturization of the semiconductor memory cells, even in the case of three-dimensional storage capacitors additional possibilities are being sought for simultaneously reducing the area requirement and increasing the capacitor capacitance.

Material combinations composed of silicon dioxide and/or silicon nitride are conventionally used as a dielectric interlayer in storage capacitors. For sub-100 nm structures, however, consideration is being given to replacing the conventionally used silicon dioxide and/or silicon nitride layers by materials which are distinguished by a higher dielectric constant and thus enable the area-specific storage capacitance to be increased. In particular, binary oxides such as aluminum oxide, tantalum oxide, hafnium oxide, zirconium oxide, oxides of the lanthanum group, aluminum oxide compounds and further individual and mixed oxides are under discussion as such high-k dielectrics.

However, many of the envisaged high-k dielectrics can be integrated only with very great difficulty into the standard process for producing storage capacitors in the context of silicon planar technology and in particular can be formed as extremely thin layers only with difficulty. Furthermore, the breakdown strength of many envisaged high-k dielectrics is inadequate for use in DRAM storage capacitors, in particular as far as the long-term stability is concerned. It has been shown, moreover, that increased leakage currents occur in the case of many of the high-k dielectrics considered in comparison with the conventional material combinations composed of silicon dioxide and/or silicon nitride, said leakage currents resulting in a shortened retention time of the charge in the storage capacitor.

When using high-k dielectrics in the context of silicon planar technology, it has furthermore emerged that such layers lead to high tensile stresses on the semiconductor surface, which in turn entails warpage of the semiconductor wafer. When using three-dimensional storage capacitors in the context of DRAM production, warpages of several 100 μm can occur in this case on account of the enlarged surface, which makes it virtually impossible to effect the further processing of the semiconductor substrate for the purposes of forming components in the context of silicon planar technology, in which layers have to be applied successively in a positionally accurate manner. There is also the risk of the semiconductor wafer breaking on account of the high strain.

These disadvantages also apply particularly when using aluminum oxide (Al₂O₃) as high-k dielectric in storage capacitors, the preferred candidate for replacing the conventional material combinations composed of silicon dioxide and/or silicon nitride. Aluminum oxide is distinguished by the fact that it can be integrated relatively simply into the standard process for producing storage capacitors in the context of silicon planar technology. During the production of storage capacitors with aluminum oxide as a dielectric interlayer in the context of silicon planar technology, a diffusion barrier is applied to a first capacitor electrode, which is generally a highly doped silicon layer, and aluminum oxide is then deposited, which is thermally densified by means of a high-temperature process in order to improve the breakdown strength, in order to reduce the leakage current and in order to increase the dielectric constant. A second capacitor electrode layer, preferably a metal layer, is subsequently applied to the aluminum oxide layer.

In order to achieve a sufficient breakdown strength in conjunction with a leakage current that is not excessively high, the densified aluminum oxide layer must have a thickness of at least 5 nm, which leads to a high tensile stress on the substrate surface, which brings about overlay problems during the subsequent processing. When using aluminum oxide as a high-k dielectric in storage capacitors, it has furthermore been shown that the breakdown strength decreases greatly over the lifetime of the storage capacitor, that is to say that so-called soft breakdowns occur.

### SUMMARY OF THE INVENTION

Various aspects of the present invention can provide particular advantages with respect to a storage capacitor, a memory and a computer system and a method for producing a storage capacitor.

According to a first embodiment of the invention a storage capacitor includes a first electrode layer, second electrode layer and a dielectric interlayer arranged between the first electrode layer and the second electrode layer. The dielectric interlayer contains a high-k dielectric and at least one silicon-containing component.

According to a second embodiment of the invention a storage capacitor includes a first electrode layer, a second electrode layer and a dielectric interlayer arranged between the first electrode layer and the second electrode layer. The dielectric interlayer is a mixed layer containing a high-k dielectric and a further silicon-containing component.

According to a third embodiment of the invention a memory includes a memory cell having a storage capacitor and a selection transistor, the storage capacitor comprising a first electrode layer, a second electrode layer and a dielectric interlayer arranged between the first electrode layer and the second electrode layer. The dielectric interlayer contains a high-k dielectric and at least one silicon-containing component.

According to a fourth embodiment of the invention a computer system includes a storage capacitor having a first electrode layer, a second electrode layer and a dielectric interlayer arranged between the first electrode layer and the second electrode layer. The dielectric interlayer contains a high-k dielectric and at least one silicon-containing component.

According to a fifth embodiment of the invention a method for producing a storage capacitor includes the steps of forming a first electrode layer, forming a dielectric interlayer on the first electrode layer and forming a second electrode layer on the dielectric interlayer. The dielectric interlayer contains a high-k dielectric and at least one silicon-containing component.

### BRIEF DESCRIPTION OF THE DRAWINGS

These above recited features of the present invention will become clear from the following description, taking in conjunction with the accompanying drawings. It is to be noted, however, that the accompanying drawings illustrate only typical embodiments of the present invention and are, therefore, not to be considered limiting of the scope of the invention. The present invention may admit other equally effective embodiments.

FIG. 1 shows a circuit diagram of a DRAM cell.

FIG. 2 shows a schematic cross section through a DRAM cell comprising a storage capacitor according to the invention in the form of a trench capacitor.

FIGS. 3A to 3E show a method for producing a storage capacitor according to the invention in the context of a standard DRAM process sequence.

### DESCRIPTION OF THE PREFERRED EMBODIMENTS

The invention is explained on the basis of trench capacitors produced in the context of a standard process sequence for forming DRAM memory cells on the basis of silicon. As an alternative to trench capacitors, however, other storage capacitor forms may also be realized in the manner according to the invention, in particular three-dimensional storage capacitor forms. One such three-dimensional storage capacitor that may be embodied in the form according to the invention is e.g. the stacked capacitor.

The trench capacitors according to the invention are formed with the aid of the planar technique, consisting of a sequence of individual processes that in each case act over the whole area of the wafer surface, a local change in the substrate being carried out in a targeted manner by means of suitable masking steps. In the production of large scale integrated circuits comprising storage capacitors, in particular DRAMs, a multiplicity of storage capacitors are formed simultaneously. However, the invention is illustrated below only with regard to the formation of an individual storage capacitor as a trench capacitor.

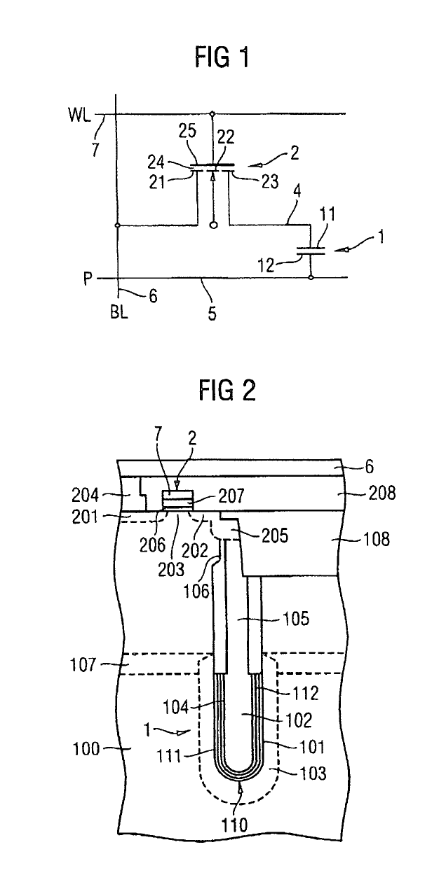

One-transistor cells are predominantly used in DRAM memories, the circuit diagram of said cells being shown in FIG. 1. Said transistor cells comprise a storage capacitor 1 and a selection transistor 2. The selection transistor 2 is preferably formed as a field effect transistor and has a first electrode 21 and a second electrode 23, between which an active region 22 is arranged, in which a current-conducting channel can be formed between the first electrode 21 and the second electrode 23. There are formed above the active region 22 an insulator layer 24 and a gate electrode 25, which act like a plate capacitor by means of which it is possible to influence the charge density in the active region 22.

The second electrode 23 of the selection transistor 2 is connected to a first electrode 11 of the storage capacitor 1 via an electrical connection 4. A second electrode 12 of the storage capacitor 1 is in turn connected to a conductive connection 5, which is preferably common to all the storage capacitors of the DRAM memory. The first electrode 21 of the selection transistor 3 is furthermore connected to a bit line 6 in order that the information stored in the storage capacitor in the form of charges can be read in and out. In this case, the reading-in or reading-out operation is controlled via a word line 7 connected to the gate electrode 25 of the selection transistor 2 in order, through the presence of a voltage, to produce a current-conducting channel in the active region 22 between the first electrode 21 and the second electrode 23 of the selection transistor 2.

Trench capacitors are in many cases used as storage capacitors in dynamic memory cells since a significant shrinking of the memory cell area can be achieved by means of the three-dimensional structure. With increasing miniaturization of the memory cells, however, additional measures are necessary in the case of a scaling size of below 100 nm in order to be able to meet the three basic requirements made of a dynamic memory cell in a DRAM memory, namely a sufficiently large storage capacitance of approximately 25 to 40 fF, which is necessary for reliable detection of the charge stored in the storage capacitor, a packing-dense and structure-friendly cell layout, which provides for a minimum chip area and thus for reduced costs, and also a high electrical performance, that is to say a long retention time of the charge in the storage capacitor, a high breakdown strength and a long lifetime.

In order to provide for a sufficient storage capacitance given a reduced storage capacitor cross section, the dielectric interlayer composed of silicon dioxide and/or silicon nitride that is conventionally used between the two capacitor electrodes in the storage capacitors is replaced according to the invention by a high-k dielectric having a higher dielectric constant. This procedure makes it possible to shrink the capacitor dimensions and at the same time to achieve a storage capacitance required for the reliable detection of the charge contained in the storage capacitor.

In this case, preferred materials are binary oxides such as e.g. aluminum oxide (Al₂O₃), tantalum oxide (Ta₂O₅), hafnium oxide (HfO₂) and also zirconium oxide (ZrO₂). Lanthanum oxide (La₂O₃) and yttrium oxide (Y₂O₃) may also be used. Furthermore, aluminum oxide compounds are appropriate as high-k dielectrics. In particular compounds with hafnium, zirconium and lanthanum, for example Hf—Al—O, Zr—Al—O or La—Al—O, are suitable for this purpose. Furthermore, high-k dielectrics may also be produced from silicate compounds such as e.g. Hf—Si—O, Zr—Si—O, La—Si—O or Y—Si—O. In addition, further individual or mixed oxides, e.g. nitrides of the fourth or fifth secondary group and of the third and fourth main groups, are suitable as high-k dielectrics.

In the standard process sequence for forming storage capacitors with the aid of silicon planar technology, however, problems occur both as far as the integration into the standard process sequence is concerned and as far as the electrical properties are concerned. This also holds true in particular for aluminum oxide, currently the most promising high-k dielectric candidate for replacing the conventional dielectric interlayers composed of silicon dioxide and/or silicon nitride.

Thus, the use of high-k dielectric layers leads to a high tensile loading on the semiconductor wafer, in particular of those with three-dimensional storage capacitor forms, which entails severe flexure of the semiconductor wafer. This warpage of the semiconductor wafer makes it virtually impossible to effect the further processing of the wafer in the context of planar technology for the formation of further electrical structures since the overlay accuracy of the successive layer can no longer be ensured.

Reliability problems furthermore occur when using high-k dielectric layers as dielectric interlayers in storage capacitors. This holds true particularly for the breakdown strength, which often deteriorates significantly over the lifetime of the storage capacitor in the case of high-k dielectrics. At the same time, in storage capacitors comprising high-k dielectrics, high leakage currents occur which greatly reduce the retention time of the charge in the storage capacitor and thus lead to short refresh cycles of the DRAM memory cells.

In order to minimize one or more of the above disadvantages when using high-k dielectrics as dielectric interlayers in storage capacitors, the dielectric interlayer according to the invention, in the storage capacitors, has a silicon-containing component alongside the high-k dielectric. Said silicon-containing component ensures that the tensile stress exerted on the substrate surface by the high-k dielectric is reduced, and in the best case is entirely compensated for. This preferably holds true when the dielectric interlayer comprises a layer stack having at least two layers, one layer being produced from the high-k dielectric and the other layer having the silicon-containing component. Given the layer thickness of the high-k dielectric of 2 nm to 10 nm, preferably 2.5 nm, the thickness of the layer having the silicon-containing component should be between 0.5 nm and 5 nm, preferably 2.5 nm. The layer having the silicon-containing component generates a compressive stress counter to the tensile stress exerted by the high-k dielectric.

Furthermore, the additional silicon-containing layer provides for a reduced leakage current in comparison with a dielectric interlayer having only a high-k dielectric layer. The breakdown strength of the dielectric interlayer, in particular as far as the long-term stability thereof is concerned, is also significantly reduced by the additional layer having silicon.

At the same time, the additional silicon-containing layer provides for an increase in the capacitance of the dielectric interlayer since the silicon-containing layer, particularly if it comprises silicon oxynitride, itself has a dielectric effect and, during the subsequent application of the high-k dielectric, prevents this from forming in crystalline fashion. However, an amorphous high-k dielectric layer has a higher dielectric constant in comparison with one with a crystalline layer construction.

As an alternative or in addition to the introduction of a silicon-containing component into the dielectric interlayer as an independent layer, according to the invention there is the possibility of forming a mixed layer comprising a high-k dielectric and the silicon-containing component or a further silicon-containing component. In this case, the proportion of the silicon-containing component in the mixed layer is preferably between 5% and 70%, preferably approximately 30%. This holds true particularly when the silicon-containing component is silicon dioxide. The admixture of the silicon-containing component with the high-k dielectric in turn provides for a high breakdown strength, an improved long-term stability and a higher capacitance, since a crystallization of the high-k dielectric during application is prevented by the admixture.

In addition, it is preferably the case that with a two-layer construction, the proportion of the silicon-containing component in the mixed layer increases toward the interface with the layer having the further silicon-containing component, since the electrical and mechanical properties are additionally improved thereby.

FIG. 2 shows one possible embodiment of a storage capacitor 1 according to the invention as a trench capacitor. In this case, the trench capacitor 1 is formed in a preferably monocrystalline silicon substrate 100. The silicon substrate 100 is preferably weakly p doped e.g. with boron. A trench 101 is embodied in the silicon substrate 100, said trench being composed of a narrower upper trench region and a wider lower trench region. Such a trench form can be produced e.g. by means of a two-stage etching process, thereby producing the bottle form of the trench 101 as shown in FIG. 2. A heavily n doped layer 103 is formed around a first lower section of the trench 101, said layer being doped with arsenic, for example. This n⁺-doped layer, as a buried plate, forms the outer capacitor electrode of the trench capacitor 1.

A dielectric layer 110 comprising two layers is furthermore formed on the trench wall in the lower region. In this case, the first layer 111 is preferably a silicon oxynitride layer having a thickness of 0.5 nm to 5 nm, and the second layer 112 is an aluminum oxide layer having a thickness of 2 nm to 10 nm, which preferably has a 30% strength admixture of silicon dioxide. As an alternative, there is the possibility of also using a different silicon-containing material combination, e.g. silicon dioxide, instead of silicon oxynitride as the base layer. One of the abovementioned high-k dielectrics may also be used as the high-k dielectric as an alternative to aluminum oxide. As the admixture with said high-k dielectric, it is also possible to use a different silicon-containing component such as silicon nitride instead of silicon dioxide. The admixture can also be completely dispensed with. When the second layer 112 is a mixed layer, there is also the possibility of completely omitting the first layer 111. It is furthermore preferably the case that with a two-layer construction, the proportion of the silicon-containing component in the mixed layer 112 increases toward the interface with the layer 111 having the further silicon-containing component.

An inner capacitor electrode 104 is in turn preferably applied as a metal layer on the dielectric interlayer 110. In this case, titanium nitride is preferably used as the metal. The trench 101 is then filled with an n⁺-doped filling layer 105, preferably a polysilicon layer. As an alternative, there is also the possibility of filling the entire inner trench region with the metal layer 104 or of forming said layer over the entire trench length. In the second case, it is then no longer necessary for the filling layer 105 to be formed in conducting fashion.

The selection transistor 2 of the DRAM cell in the embodiment shown in FIG. 2 has two diffusion regions 201, 202, which are produced by implantation of doping atoms into the silicon substrate 100 and are separated by a channel 203. The first diffusion region 201 serves as a first electrode layer 21 of the selection transistor 2 and is connected to a bit line 6 by a contact layer 204. The second diffusion region 202 is connected by a capacitor connection 205 to the n⁺-doped filling layer 105, which, with the metal layer 104, forms the inner capacitor electrode of the trench capacitor. The channel 203 is furthermore isolated from a gate electrode layer 207, which is part of a word line 7, by a dielectric layer 206.

In the upper region of the trench, in a manner adjoining the dielectric layer, an insulator layer 106 is provided between the trench wall and the filling layer 105 of the trench capacitor 1. Said insulator layer 206 prevents a parasitic transistor from forming along the trench between the capacitor connection 205 and the buried plate 103. In this case, silicon dioxide is preferably used as the insulator layer 106. Furthermore, an n⁺-doped well 107 is provided in the silicon substrate, said well serving as connection of the buried plate 103 to the buried plates of the further DRAM memory cells. An isolation trench 108 (STI isolation) is formed in order to insulate the DRAM cells from one another. The gate electrode layer 207 and the word line 7 are insulated from the bit line 6 in contact layer 204 by an oxide layer 208.

A reading-in and reading-out operation of the DRAM cell is controlled by means of the word line 7 connected to the gate electrode layer 207 of the selection transistor in order, by the application of a voltage, to produce a current-conducting channel 103 between the diffusion regions 201, 202, so that information in the form of charge can be read in and out in the metal layer 104 in the trench 101 via the connection layer 205.

The design according to the invention of the dielectric interlayer composed of a high-k dielectric with an additional silicon-containing component makes it possible to improve the electrical performance of the trench capacitor and thus of the DRAM cell and at the same time to reduce surface stress.

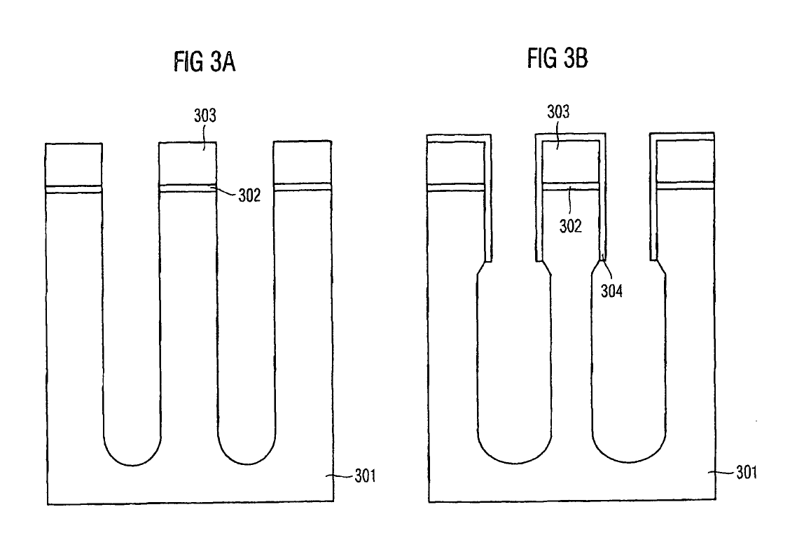

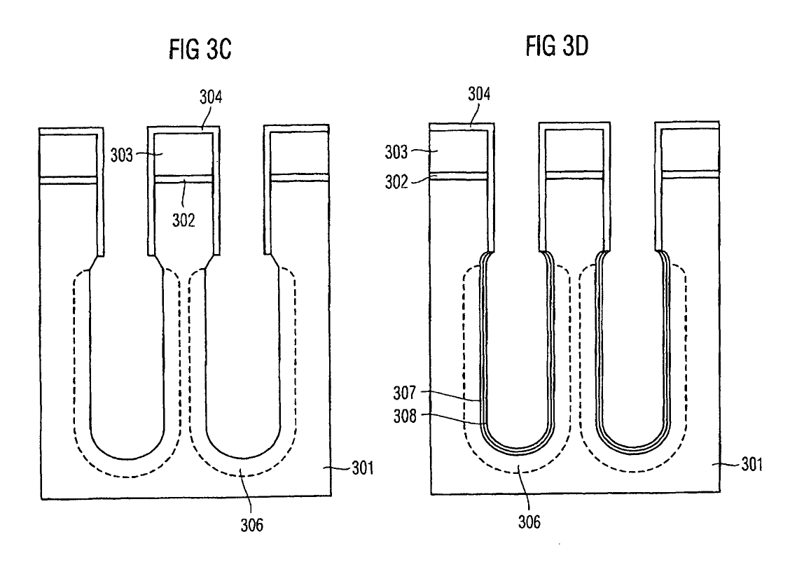

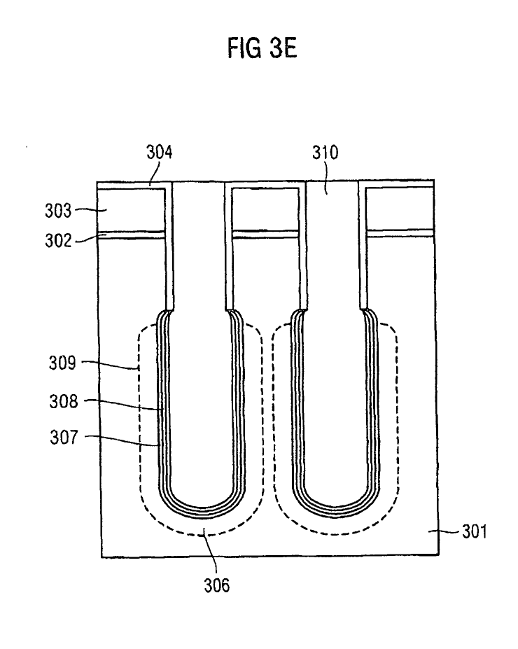

FIGS. 3A to 3E show a method for producing storage capacitors according to the invention as a trench capacitor comprising a dielectric interlayer composed of an SiON layer and an Al₂O₃ layer containing an SiO₂ admixture in the context of a standard DRAM process.

As illustrated in FIG. 3A, in a first process step, the trenches (two are shown) for the trench capacitors are formed in a p⁻-doped silicon substrate 301. For this purpose, an oxide layer 302 and a nitride layer 303 are successively produced on the silicon surface. Afterward, by means of a mask layer, the regions of the trench capacitors are defined on the silicon surface in a known manner and trenches having a depth of up to 10 μm are etched by means of a first etch.

In a next process step, a thin etching-resistant layer 304 is then deposited in order to cover the upper region of the trench. The etching-resistant layer 304 serves as an etching mask for a further etching step, during which the trenches are expanded in the lower trench region. A cross section through the silicon wafer after this process step is illustrated in FIG. 3B.

In a further process sequence, the n⁺-doped buried plate 306 is formed. For this purpose, the silicon substrate is doped with arsenic in such a way as to produce the n⁺-doped layer 306 around the extended region of the trench. A cross section through this silicon wafer after this process step is illustrated in FIG. 3C.

In a further process sequence, a dielectric interlayer is then formed in the manner according to the invention. For this purpose, in a first step, preferably thermally, a silicon nitride layer is grown in the lower widened section on the trench wall. Said silicon nitride layer is then partly oxidized, up to preferably a maximum of 50%, in order to convert the silicon nitride layer into a silicon oxynitride layer 307. In this case, the layer thickness is preferably between 0.5 nm and 5 nm, in particular 2.5 nm. After the production of the silicon oxynitride layer 307, a high-k dielectric layer 308, aluminum oxide in the embodiment shown, is then applied. During the application of the aluminum oxide, silicon dioxide is in this case admixed, preferably with a proportion of 30%. In this case, the aluminum oxide layer with the silicon dioxide admixture preferably has a thickness of 2 nm to 10 nm, in particular a thickness of 2.5 nm. In addition, it is preferred for the proportion of the silicon dioxide to increase toward the interface with the silicon oxynitride layer 307. The dielectric layer is subsequently subjected to a high-temperature step in order to densify the high-k dielectric. A cross section through the silicon wafer after this process step is illustrated in FIG. 3D.

In a further process sequence, the inner capacitor electrode is then produced by the application of a thin metal layer 308, preferably titanium nitride, on the dielectric interlayer. The trench is subsequently filled with a conductive filling layer 310, preferably n⁺-doped polysilicon. A cross section through the silicon wafer after this process step is illustrated in FIG. 3E. The storage capacitor can then be coupled to a selection transistor in the context of the known standard process sequence in order to produce DRAM memory cells.

With the dielectric interlayer according to the invention in storage capacitors, memories and computer systems, which has a high-k dielectric and a silicon-containing component, there is the possibility of improving the electrical properties of the storage capacitor as far as breakdown strength, long-term stability and capacitance are concerned, and at the same time of enabling an improved integration into the standard process sequences for forming large scale integrated circuits.

According to the invention, any of a storage capacitor, a memory and a computer system, comprising a first and a second electrode layer has a dielectric interlayer that is arranged between the first and second electrode layers and contains a high-k dielectric and at least one silicon-containing component.

As a result of the formation of the dielectric interlayer with a high-k dielectric and a silicon-containing component, there is the possibility, in comparison with the conventional material combination composed of silicon dioxide and/or silicon nitride for forming the dielectric interlayer in the case of storage capacitors, of significantly increasing the dielectric constant, whereby the storage capacitor dimensioning can be shrunk particularly in DRAM applications in conjunction with reliable detection of the charge content.

In this case, the additional use of a silicon component in the dielectric interlayer in comparison with an interlayer that exclusively consists of a high-k dielectric provides for improved electrical properties. The silicon addition can on the one hand contribute to the further increase in the storage capacitance, since the silicon component prevents a crystalline formation of the high-k dielectric, which leads to a higher dielectric constant. However, the silicon component also makes it possible to achieve an increased breakdown strength in comparison with a pure high-k dielectric. Furthermore, the long-term stability of the storage capacitor can be improved by the silicon component in the high-k dielectric layer. By virtue of the silicon component, it is also possible to significantly reduce the strain of the semiconductor wafer on account of the tensile stress caused by the high-k dielectric, and consequently to reduce flexure of the semiconductor wafer, whereby it is possible to significantly improve the overlay accuracy during the application of further structures on the semiconductor wafer.

According to the invention, the dielectric interlayer is a layer stack having at least two layers, one layer having the high-k dielectric and the other layer having the silicon-containing component. It is preferred in this case for the high-k dielectric layer to have a thickness of between 2 nm and 10 nm, in particular 2.5 nm, and for the layer having the silicon component to be formed with a thickness of between 0.5 nm and 5 nm, in particular 2.5 nm. It is advantageous, moreover, if the silicon-containing component is SiON. The two-layered configuration of the dielectric interlayer makes it possible largely to compensate for the warpage of the semiconductor wafer due to the high-k dielectric layer, which occurs particularly in the case of three-dimensional storage capacitor structures on account of the significantly enlarged surface, since the silicon-containing component generates a compressive loading against the tensile loading of the dielectric layer, which results in stress equalization.

This holds true particularly when the silicon-containing component is SiON. This is because an SiON layer can be formed in a particularly simple manner in the context of standard silicon planar technology. In the case of storage capacitors, a diffusion barrier is applied to the first capacitor electrode layer, which is generally a doped silicon layer, in order to prevent diffusion of the dopants from the silicon substrate into the dielectric and conversely of constituents from the dielectric into the silicon substrate. In this case, silicon nitride is generally used as the diffusion barrier, said silicon nitride preferably being produced thermally. By simple thermal oxidation, such a silicon nitride layer can be converted into a silicon oxynitride layer.

The two-layer construction furthermore also provides for an improvement in the electrical properties, primarily as far as the breakdown strength and the reduction of the leakage current are concerned, in particular also when an SiON layer is used. Furthermore, the lifetime of the storage capacitors is improved, that is to say that the risk of soft breakdowns is significantly reduced in comparison with a pure high-k dielectric in the storage capacitor.

In addition, there is the possibility, in accordance with one preferred embodiment according to the invention, of forming the layer having the high-k dielectric as a mixed layer comprising the high-k dielectric and a further silicon-containing component. In this case, the proportion of the silicon-containing component is preferably between 5% and 70% and in turn with preference approximately 30%, the silicon-containing mixed component preferably being silicon dioxide. It is preferred, moreover, for the proportion of the further silicon-containing component in the mixed layer to increase toward the interface with the layer having the silicon-containing component.

As an alternative, however, it is also possible for the entire dielectric interlayer to be formed as a mixed layer comprising the high-k dielectric and the silicon-containing component. In this case, the proportion of the silicon-containing component is in turn preferably between 5% and 70%, with preference approximately 30%, the silicon-containing mixed component preferably being silicon dioxide.

In comparison with a pure high-k dielectric layer, the mixed layer construction leads to improved electrical properties, in particular an increase in the breakdown strength and greater long-term stability. In addition, an increased capacitance can also be achieved through the silicon addition since the silicon addition prevents a recrystallization of the high-k dielectric. This is because the high-k dielectric present in the amorphous state is distinguished by a larger dielectric constant in comparison with the crystalline high-k dielectric. The silicon addition to the high-k dielectric layer furthermore provides for a reduction of the tensile stress on the semiconductor wafer and thus for a reduced warpage of the semiconductor wafer.

In the case of a two-layer construction with a mixed layer, the rise in the proportion of the silicon-containing component in the mixed layer toward the interface with the layer having the further silicon-containing component results in an additional improvement in the mechanical and electrical properties.

According to the invention, the storage capacitor has a so-called MIS (metal-insulator-silicon) construction, the first capacitor electrode layer being arsenic-doped silicon substrate that is formed around a trench, the dielectric interlayer being embodied on the trench wall and preferably containing aluminum oxide as high-k dielectric and silicon oxide as admixture and being embodied on a silicon oxynitride layer. A metal layer, preferably titanium nitride, is then applied on the dielectric interlayer as a second capacitor electrode layer. Such a storage capacitor formed as a trench capacitor is distinguished by a high capacitance in conjunction with a high breakdown strength and a long lifetime, hardly any warpage of the semiconductor substrate occurring.

The preceding description describes advantageous exemplary embodiments of the invention. The features disclosed therein and the claims and the drawings can, therefore, be useful for realizing the invention in its various embodiments, both individually and in any combination. While the foregoing is directed to embodiments of the present invention, other and further embodiments of this invention may be devised without departing from the basic scope of the invention, the scope of the present invention being determined by the claims that follow.

We claim:

1. A storage capacitor comprising
a first electrode layer,
a second electrode layer, and
a dielectric interlayer arranged between the first electrode layer and the second electrode layer,
the dielectric interlayer containing a high-k dielectric and at least one silicon-containing component.

2. The storage capacitor as claimed in claim 1, wherein the dielectric interlayer is a layer stack having at least two layers, one layer containing the high-k dielectric and the other layer containing the silicon-containing component.

3. The storage capacitor as claimed in claim 2, wherein the layer having the silicon-containing component has a thickness of 0.5 nm to 5 nm.

4. The storage capacitor as claimed in claim 2, wherein the layer having the silicon-containing component has a thickness of 2.5 nm.

5. The storage capacitor as claimed in claim 2, wherein the silicon-containing component is SiON.

6. The storage capacitor as claimed in claim 2, wherein the layer having the high-k dielectric has a thickness of 2 nm to 10 nm.

7. The storage capacitor as claimed in claim 2, wherein the layer having the high-k dielectric has a thickness of 2.5 nm.

8. The storage capacitor as claimed in claim 1, wherein the dielectric interlayer has a mixed layer containing the high-k dielectric and the silicon-containing component.

9. The storage capacitor as claimed in claim 8, wherein the proportion of the silicon-containing component is between 5% and 70%.

10. The storage capacitor as claimed in claim 8, wherein the proportion of the silicon-containing component is approximately 30%.

11. The storage capacitor as claimed in claim 8, wherein the silicon-containing component is SiO₂.

12. The storage capacitor as claimed in claim 1, wherein the high-k dielectric is Al₂O₃.

13. A storage capacitor comprising
a first electrode layer,
a second electrode layer, and
a dielectric interlayer arranged between the first electrode layer and the second electrode layer,
the dielectric interlayer being a mixed layer containing a high-k dielectric and a further silicon-containing component.

14. The storage capacitor as claimed in claim 13, wherein the proportion of the further silicon-containing component is between 5% and 70%.

15. The storage capacitor as claimed in claim 13, wherein the proportion of the further silicon-containing component is approximately 30%.

16. The storage capacitor as claimed in claim 13, wherein the proportion of the further silicon-containing component in the mixed layer increases toward the interface with the layer having the silicon-containing component.

17. The storage capacitor as claimed in claim 13, wherein the silicon-containing component is SiO₂.

18. The storage capacitor as claimed in claim 13, wherein the high-k dielectric is Al₂O₃.

19. A memory including a memory cell having a storage capacitor and a selection transistor, the storage capacitor comprising
a first electrode layer,
a second electrode layer, and
a dielectric interlayer arranged between the first electrode layer and the second electrode layer, the dielectric interlayer containing a high-k dielectric and at least one silicon-containing component.

20. The memory as claimed in claim 19, wherein the storage capacitor
a trench is embodied in a semiconductor substrate, the first electrode layer being formed in the semiconductor substrate around the trench,
the dielectric interlayer being embodied on the trench wall, and
the second electrode layer being arranged on the dielectric interlayer.

21. The memory as claimed in claim 19, wherein the dielectric interlayer is a layer stack having at least two layers, one layer containing the high-k dielectric and the other layer containing the silicon-containing component.

22. The memory as claimed in claim 19, wherein the dielectric interlayer has a mixed layer containing the high-k dielectric and the silicon-containing component.

23. The memory as claimed in claim 19, wherein the second electrode layer comprises TiN.

24. The memory as claimed in claim 19, wherein the semiconductor substrate is a silicon substrate and the first electrode layer is formed by an arsenic doping of the silicon substrate around the trench.

25. A computer system including a storage capacitor comprising
a first electrode layer,
a second electrode layer, and
a dielectric interlayer arranged between the first electrode layer and the second electrode layer, the dielectric interlayer containing a high-k dielectric and at least one silicon-containing component.

26. The computer system as claimed in claim 25, wherein the dielectric interlayer is a layer stack having at least two layers, one layer containing the high-k dielectric and the other layer containing the silicon-containing component.

27. The computer system as claimed in claim 26, wherein the layer having the silicon-containing component has a thickness of 0.5 nm to 5 nm.

28. The computer system as claimed in claim 26, wherein the silicon-containing component is SiON.

29. The computer system as claimed in claim 26, wherein the layer having the high-k dielectric has a thickness of 2 nm to 10 nm.

30. The computer system as claimed in claim 25; wherein the dielectric interlayer has a mixed layer containing the high-k dielectric and the silicon-containing component.

31. The computer system as claimed in claim 30, wherein the proportion of the silicon-containing component is between 5% and 70%.

32. The computer system as claimed in claim 30, wherein the silicon-containing component is SiO₂.

33. The computer system as claimed in claim 30, wherein the proportion of the further silicon-containing component in the mixed layer increases toward the interface with the layer having the silicon-containing component.

34. The computer system as claimed in claim 25, wherein the high-k dielectric is Al₂O₃.

35. A method for producing a storage capacitor comprising:
forming a first electrode layer,
forming a dielectric interlayer on the first electrode layer, and
forming a second electrode layer on the dielectric interlayer,
the dielectric interlayer containing a high-k dielectric and at least one silicon-containing component.

36. The method as claimed in claim 35, wherein the dielectric interlayer is formed as a layer stack having at least two layers, one layer containing the high-k dielectric and the other layer containing the silicon-containing component.

37. The method as claimed in claim 36, wherein the following method steps are carried out for the purpose of forming the layer having the silicon-containing component:
applying an SiN layer on the first electrode layer, and
partly oxidizing the SiN layer in order to form an SiON layer.

38. The method as claimed in claim 36, wherein the layer having the high-k dielectric is formed as a mixed layer comprising the high-k dielectric and a further silicon-containing component.

39. The method as claimed in claim 38, wherein the proportion of the further silicon-containing component is between 5% and 70%.

40. The method as claimed in claim 36, wherein the further silicon-containing component is SiO₂.

41. The method as claimed in claim 35, wherein the dielectric interlayer is formed as a mixed layer comprising the high-k dielectric and the silicon-containing component.

42. The method as claimed in claim 41, wherein the proportion of the silicon-containing component is between 5% and 70%.

43. The method as claimed in claim 41, wherein the silicon-containing component is SiO₂.

44. The method as claimed in claim 35, wherein the high-k dielectric is Al₂O₃.

45. The method as claimed in claim 35, wherein
a trench is embodied in a semiconductor substrate, the first electrode layer being formed in the semiconductor substrate around the trench,
the dielectric interlayer being embodied on the trench wall, and
the second electrode layer being formed on the dielectric interlayer.

46. The method as claimed in claim 35, wherein the second electrode layer is formed from TiN.

47. The method as claimed in claim 35, wherein the semiconductor substrate is a silicon substrate and the first electrode layer is formed by an arsenic doping of the silicon substrate around the trench.
